(19) United States
(12) Patent Application Publication
(10) Pub. No.: US 2025/0341781 A1
(43) Pub. Date: Nov. 6, 2025

(54) PASSIVE INTEGRATED OPTICAL SYSTEMS AND METHODS FOR REDUCTION OF SPATIAL OPTICAL COHERENCE

(71) Applicant: ASML NETHERLANDS B.V., Veldhoven (NL)

(72) Inventors: Irwan Dani SETIJA, Utrecht (NL); Sergei SOKOLOV, Eindhoven (NL)

(73) Assignee: ASML NETHERLANDS B.V., Veldhoven (NL)

(21) Appl. No.: 18/859,981

(22) PCT Filed: Apr. 18, 2023
(86) PCT No.: PCT/EP2023/060046

§ 371 Date: Oct. 24, 2024

Related U.S. Application Data
(60) Provisional application No. 63/342,305, filed on May 16, 2022.

(51) Int. Cl. G03F 7/00

(52) U.S. Cl. CPC G03F 7/70091; G03F 7/70075; G03F 7/70633

(57) ABSTRACT

Passive integrated optical systems and methods are described. The present systems and methods facilitate reduction of spatial optical coherence in source radiation used for metrology, for example. Current coherence scramblers used for metrology typically include one or more (moving) mechanical components configured to reduce the coherence of source radiation. However, these mechanical coherence scramblers occupy volume within a system and introduce the threat of mechanical wear and/or failure. In contrast, the present systems and methods utilize a combination of passive integrated optical elements to form a coherence scrambler. This reduces or eliminates the use of mechanical components and increases durability, among other advantages.

### CROSS-REFERENCE TO RELATED APPLICATIONS

This application claims priority of U.S. application 63/342,305 which was filed on May 16, 2022 and which is incorporated herein in its entirety by reference.

### TECHNICAL FIELD

This description relates to optical systems and methods for metrology.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). Metrology is an integral part of these fine-tuning steps

### SUMMARY

Passive integrated optical systems and methods are described. The present systems and methods facilitate reduction of spatial optical coherence in source radiation used for metrology, for example. Current coherence scramblers used for metrology typically include one or more (moving) mechanical components configured to reduce the coherence of source radiation. However, these mechanical coherence scramblers occupy volume within a system and introduce the threat of mechanical wear and/or failure. In contrast, the present systems and methods utilize a combination of passive integrated optical elements to form a coherence scrambler. This reduces or eliminates the use of mechanical components and increases durability, among other advantages.

According to an embodiment, a system configured to convert spatially coherent radiation to completely or partially spatially incoherent radiation is provided. The system comprises a splitter configured to receive and split the spatially coherent radiation into channels. The system comprises optical pathways having different lengths coupled to the channels. The different lengths are configured to convert the spatially coherent radiation to the completely or partially spatially incoherent radiation. The system comprises a combiner coupled to the optical pathways and configured to combine the completely or partially spatially incoherent radiation from the optical pathways into a single multimode output.

In some embodiments, the optical pathways are configured such that radiation in a single channel does not become incoherent since it is single mode radiation, but with an appropriate path difference, radiation in the single channel becomes incoherent with respect to radiation in neighboring channels.

In some embodiments, the splitter, the optical pathways, and the combiner are integrated into an integrated optical body. In some embodiments, the integrated optical body comprises a microchip fabricated using complementary metal-oxide-semiconductor (CMOS) and/or indium phosphide fabrication techniques, lithographic and/or electron beam writing techniques, and/or other techniques. In some embodiments, a waveguiding layer of the integrated optical body is formed from silicon, silicon-on-oxide, indium phosphide, silicon nitride, and/or aluminum oxide.

In some embodiments, the system comprises stacked integrated optical bodies that form a multidimensional array of waveguide emitters.

In some embodiments, the system is passive, having no moving parts or electrically controlled components.

In some embodiments, the splitter is configured to split the spatially coherent radiation into at least 2-100 channels. In some embodiments, the splitter is a binary tree beam splitter or a non-binary beam splitter. In some embodiments, the splitter is a multimode interference (MMI) device.

In some embodiments, each optical pathway comprises a waveguide and forms a portion of a corresponding channel.

In some embodiments, the different lengths are configured to reduce or eliminate interference between radiation traversing different optical pathways, which converts the spatially coherent radiation to the completely or partially spatially incoherent radiation.

In some embodiments, an optical path length difference from a first optical pathway to a second optical pathway is larger than a coherence length of the spatially coherent radiation.

In some embodiments, the combiner comprises an optical fiber array. In some embodiments, the combiner comprises a photonic lantern. In some embodiments, the combiner comprises a micro lens array and/or one or more macroscopic lenses.

In some embodiments, the spatially coherent radiation comprises visible light.

In some embodiments, the system further comprises a multimode fiber configured to receive the single multimode output from the combiner.

In some embodiments, the system further comprises a controller configured to actively control output from individual optical pathways.

In some embodiments, the spatially coherent radiation is converted to the completely or partially spatially incoherent radiation for metrology associated with a semiconductor manufacturing process.

According to another embodiment, a method for converting spatially coherent radiation to completely or partially spatially incoherent radiation is provided. The method comprises: receiving and splitting, with a splitter, the spatially coherent radiation into channels; converting, with optical pathways having different lengths coupled to the channels, the spatially coherent radiation to the completely or partially spatially incoherent radiation; and combining, with a combiner coupled to the optical pathways, the completely or partially spatially incoherent radiation from the optical pathways into a single multimode output.

According to another embodiment, a system configured to convert spatially coherent radiation to completely or partially spatially incoherent radiation to reduce speckles in illumination for metrology as part of a semiconductor manufacturing process is provided. The system is configured with a combination of passive integrated optical elements such that volume and threat of mechanical wear is reduced relative to mechanical coherence scramblers. The system comprises a source configured to generate the spatially coherent radiation and a passive integrated optical body. The body comprises a splitter configured to receive and split the spatially coherent radiation into channels. The splitter comprises a binary tree beam splitter and/or a multimode interference (MMI) device. The body comprises optical pathways having different lengths coupled to the channels. The different lengths are configured to convert the spatially coherent radiation conducted by the optical pathways to the completely or partially spatially incoherent radiation. The different lengths are configured to reduce or eliminate interference between radiation traversing different optical pathways, which converts the spatially coherent radiation to the completely or partially spatially incoherent radiation. The optical pathways are configured such that radiation in a single channel does not become incoherent since it is single mode radiation, but with an appropriate path difference, radiation in the single channel becomes incoherent with respect to radiation in neighboring channels. The body comprises a combiner configured to combine the completely or partially spatially incoherent radiation from the optical pathways into a single multimode output. The system comprises a multimode fiber configured to receive the single multimode output from the combiner and direct the completely or partially spatially incoherent radiation for metrology.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a system for converting spatially coherent radiation to completely or partially spatially incoherent radiation, according to an embodiment.

FIG. 7 illustrates a splitter of the present system formed as a binary tree, according to an embodiment.

FIG. 8 illustrates optical pathways of the present system, according to an embodiment.

FIG. 9 illustrates combiner of the present system, formed by an optical fiber array, according to an embodiment.

FIG. 10 illustrates a combiner of the present system, formed by a photonic lantern, according to an embodiment.

FIG. 11 illustrates a combiner of the present system, formed by a micro lens array and a macroscopic lens, according to an embodiment.

FIG. 12 illustrates stacked integrated optical bodies, according to an embodiment.

FIG. 13 illustrates a method for converting spatially coherent radiation to completely or partially spatially incoherent radiation, according to an embodiment.

FIG. 14 is a block diagram of an example computer system, according to an embodiment.

### DETAILED DESCRIPTION

In semiconductor device manufacturing, metrology operations typically include determining the position of a metrology mark (or marks) and/or other target in a layer of a semiconductor device structure. This position is typically determined by irradiating a metrology mark with radiation, and comparing characteristics of different diffraction orders of radiation reflected from the metrology mark. Such techniques are used to measure overlay, alignment, and/or other parameters.

Prior metrology systems use strong broadband light sources for accurate characterization of weak metrology targets over a large range of wavelengths to cope with the challenges of process robustness and opaque layers, for example. One of the challenges associated with these light sources, is the coherence of the light they output. The light can come from a spatially coherent laser source, which can lead to speckles in metrology images. For scatterometry, which relies on accurate determination of angular resolved spectra, this can lead to unwanted errors. Coherence scramblers configured to reduce the coherence of light are known. One example is a rotating diffuser plate. Scattering of coherent light through a diffusing medium leads to speckles in the transmitted light. By rotating a diffuser plate, a speckle pattern varies so that measuring over a sufficiently long time averages out effects of the speckles. However, these and other mechanical coherence scramblers occupy volume within a system, introduce the threat of mechanical wear and/or failure, produce unwanted vibrations, and/or have other disadvantages. For example, existing coherence scramblers may typically be as big as a shoe box or larger. Mechanical motion limits the speed at which speckles are averaged, and therefore requires a minimal measurement time. With present metrology system requirements for switching and measurement times less than one millisecond, this becomes very challenging.

In contrast, the present systems and methods utilize a combination of passive integrated optical elements to form a coherence scrambler with no moving or electrically controlled components. This reduces or eliminates the use of mechanical components, required much less physical volume, and increases durability, among other advantages. The present systems and methods apply techniques from photonic integration and include a compact, fast, and low-cost coherence scrambling device. Coherent, wavelength filtered radiation from a source is split up into channels and provided to different optical pathways (multiple waveguides). By giving each of these optical pathways/waveguides an optical path difference with respect to its neighbors that is larger than a coherence length of the radiation, the radiation in the waveguides becomes mutually incoherent. If needed, the radiation can be recombined into a multimode fiber using a micro lens array or a photonic lantern, for example. The radiation can be further processed using other existing metrology system components. Because coherence scrambling occurs through optical pathlength differences (and not mechanical motion), integrated optical components may be used, which only occupy a very small physical volume (e.g., a volume much smaller than a typical shoebox). These and other features are each described in additional detail below.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made to the manufacture of integrated circuits (ICs) for semiconductor devices, it should be understood that the description has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

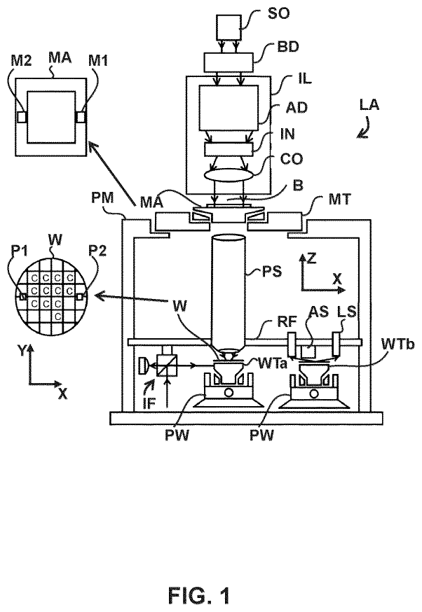

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as o-outer and o-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

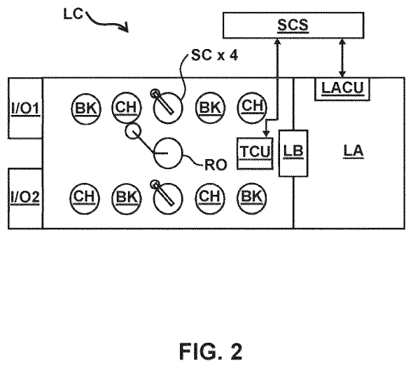

As shown in FIG. 2, the lithographic apparatus LA may form part of a lithographic cell LC, also sometimes referred to a lithocell or cluster, which also includes apparatuses to perform pre- and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

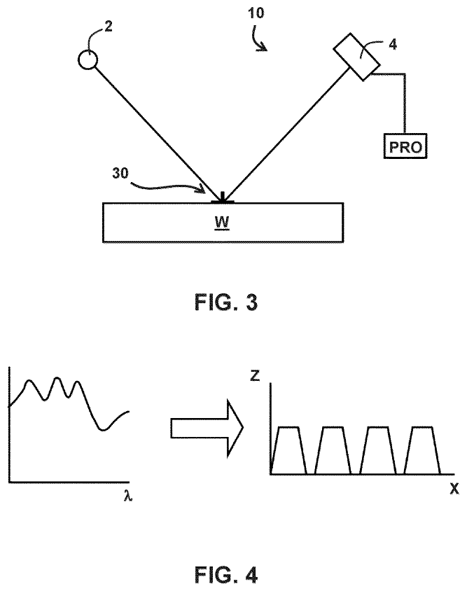

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). Redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

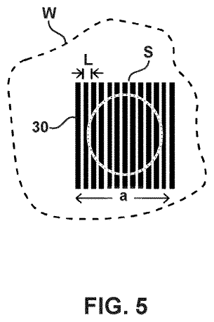

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

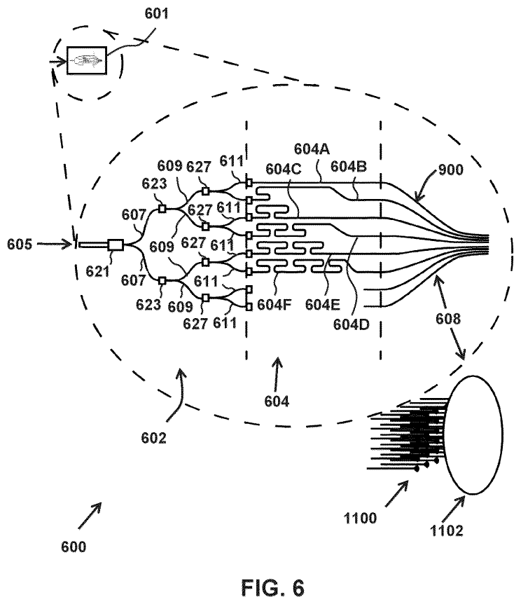

FIG. 6 illustrates a system 600 for converting spatially coherent radiation to completely or partially spatially incoherent radiation. The radiation may be used to obtain measurements from metrology targets, and/or for other uses. The radiation may comprise illumination such as visible light and/or other radiation. A target may comprise one or more metrology marks, such as diffraction grating targets, formed in a substrate such as a semiconductor wafer, for example. System 600 may form a portion of system 10 described above with respect to FIG. 3. System 600 may be a subsystem of system 10, for example. In some embodiments, one or more components of system 600 may be similar to and/or the same as one or more components of system 10. In some embodiments, one or more components of system 600 may replace, be used with, and/or otherwise augment one or more components of system 10.

System 600 provides a new optical design architecture. As described above, system 600 is a passive integrated optical system configured to reduce spatial optical coherence in source radiation used for metrology, for example. Current coherence scramblers used for metrology typically include one or more (moving) mechanical components configured to reduce the coherence of source radiation. However, these mechanical coherence scramblers occupy volume within a system and introduce the threat of mechanical wear and/or failure. In contrast, system 600 uses a combination of passive integrated optical elements to form a coherence scrambler. This reduces or eliminates the use of mechanical components and increases durability, among other advantages. System 600 comprises a splitter 602, optical pathways 604, a combiner 608, and/or other components. In some embodiments, the components of system 600 form a portion of a metrology sensor that is used in a semiconductor manufacturing process.

In some embodiments, splitter 602, optical pathways 604, combiner 608 and/or other components of system 600 are integrated into an integrated optical body 601. In some embodiments, integrated optical body 601 is passive, having no moving parts or electrically controlled components. In some embodiments, integrated optical body 601 comprises a microchip fabricated using complementary metal-oxide-semiconductor (CMOS) fabrication techniques, indium phosphide fabrication techniques, lithography and/or electron beam writing techniques, and/or other techniques, for example. Integrated optics platforms may include silicon, silicon nitride (Si₃N₄), indium phosphide (InP), aluminum oxide (AL₂O₃) (e.g., for UV radiation), and/or other plat forms. A waveguiding (optical pathway forming) layer of the integrated optical body may be formed from Si3N4 (e.g., for radiation wavelengths down to about 25-300 nm-deep UV requires an alternate material) as one example, Si, silicon-on-oxide, and/or other materials. For wavelengths 250-400 nm, for example, another material other than Si₃N₄ may be used, such as aluminum oxide (Al₂O₃) or other materials.

Using an Si3N4 integrated optics platform, for example, facilitates use of radiation with a bandwidth of about 400-1700 nm, which is sufficient for a metrology system (e.g., system 10 shown in FIG. 3) illumination. However, radiation source power can be a problem for such waveguides, which can handle up to about 1 W of optical power, in case optical powers larger than 1 W need to be processed. However, system 600 (and/or system 10 shown in FIG. 3) may be configured such that wavelength selection required for metrology is performed prior to radiation entering splitter 602, which mitigates the high radiation source power problem, since the power is reduced by limiting the bandwidth.

Splitter 602 is configured to receive (e.g., from a source) and split spatially coherent radiation into channels 607, 609, 611, etc. Radiation (e.g., light) from a single channel passed to a multimode fiber (described below) produces the (undesirable) speckles described above at the end of the multimode fiber. In contrast, splitter 602 is configured to split the spatially coherent radiation into a sufficient number of channels 607, 609, 611 needed to reduce and/or eliminate speckle effects. An estimate for 600 nm radiation (e.g., light) with a 6 nm bandwidth, for example, gives a minimum number of about 750 channels for splitter 602 (e.g., a number of channels or modes is equal to the size of the entrance aperture of a multimode fiber divided by the size of a single channel or mode which is roughly the size of a point spread function-see example mathematical details below). Photonic lantern technology (described below) combines about 100 fibers. With a fiber array followed by a micro lens array (as another example, this number can easily be extended to a few thousand. Thus, in some embodiments, the spatially coherent radiation is split by splitter 602 into at least 2-100, 2-200, 2-500, 2-750, 2-1000, 2-3000, or more channels, for example.

In some embodiments, splitter 602 comprises a binary tree beam splitter and/or other splitters. A binary tree beam splitter may include a series of channels that are successively split in half such that two channels are formed from one. After several splits, a tree structure is formed where one input channel 605 becomes a plurality of output channels 611. In some embodiments, splitter 602 comprises a multimode interference (MMI) device.

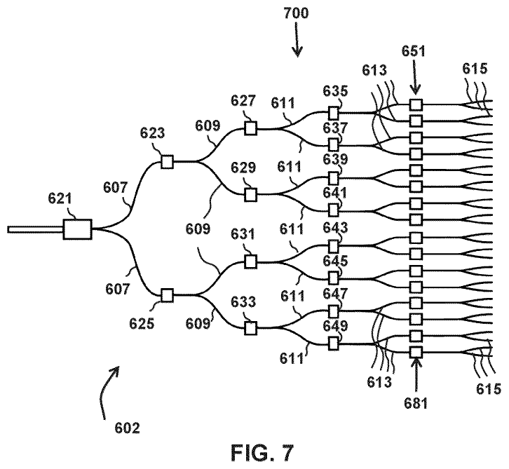

For example, FIG. 7 illustrates splitter 602 formed as a binary tree 700. Binary tree 700 includes channels 607, 609, 611, 613, 615, etc. As shown in FIG. 7, at each splitting location 621-681, one channel of radiation is split into two channels, with incident radiation at each splitting location divided evenly into the two channels. Splitting occurs because the walls of the channels are arranged such that a single channel becomes two. A dividing wall is formed in the center of a channel so that radiation is separated into two substantially equal parts. The splitting is repeated one or more times until a plurality of channels are created by splitter 602.

Returning to FIG. 6, in some embodiments, splitter 602 comprises a non-binary beam splitter and/or other splitters. In general, a binary beam splitter is one which splits one channel into two. However, in principle, non-binary splitters can also be used, e.g., ones which split one channel into three and/or some other quantity of channels. These may include, for example, a directional coupler, an ultrabroadband nanophotonic beam splitter using metamaterial, and/or other non-binary beam splitters.

Optical pathways 604 are directly coupled (e.g., without any intervening air or lens space) to corresponding channels 611. Optical pathways 604 are configured to convert the spatially coherent radiation into completely or partially spatially incoherent radiation. Each optical pathway 604a, 604b, 604c, 604d, 604e, and 604f in this example, may comprise a waveguide and form a portion of a corresponding channel 611, for example. Optical pathways 604 have different lengths and are coupled to channels 611. The different lengths are configured to convert the spatially coherent radiation conducted by optical pathways 604 to the completely or partially spatially incoherent radiation. The different lengths are configured to reduce or eliminate interference between radiation traversing different optical pathways 604, which converts the spatially coherent radiation to the completely or partially spatially incoherent radiation. Optical pathways 604 are configured such that radiation in a single channel 611 does not become incoherent since it is single mode radiation, but with an appropriate path difference, radiation in the single channel 611 becomes incoherent with respect to radiation in neighboring channels 611.

In some embodiments, an optical path length difference from a first optical pathway 604a to a second optical pathway 604b (and from first optical pathway 604a to a third optical pathway 604c, the second optical pathway 604b to the third optical pathway 604c, and so on) is larger than a coherence length of the spatially coherent radiation coming from 605. With optical pathways 604, a degree of coherence between the channels can be adjusted by changing individual optical pathlengths and/or other characteristics of optical pathways 604.

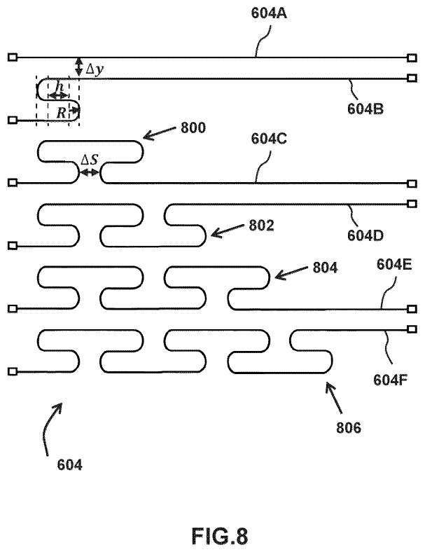

For example, FIG. 8 illustrates optical pathways 604 (including optical pathways 604a-604f). Radiation at an output of the channels (e.g., channels 611 shown in FIG. 6) is still single mode and coherent, but if each channel is configured with an optical path difference (OPD) larger than a coherence length (Lc) of the radiation, radiation from the separate channels will not interfere with each other. Such an integrated structure is formed using optical pathways 604a-604 f, which may be thought of as delay lines (where radiation reaching the end of one optical pathway is delayed compared to radiation in a different optical pathway because of path length differences-some radiation travels a longer route). FIG. 8 illustrates just one out of many possible configurations. In FIG. 8, each optical pathway 604a-604f has an OPD with respect to its neighbors imposed by an extra zig-zag curving path 800, 802, 804, 806. Each optical pathway has several tunable parameters. For example, R is a minimal radius of curvature where radiation does not leak from a pathway; As and Δy are minimal distances between pathways needed to prevent coupling; and h is a parameter that can be used to tune OPD.

By way of a non-limiting practical example, assuming a Gaussian emission spectrum, the coherence length is:

$${L}_{c} = \frac{2 ln ( 2 )}{π} \frac{{λ}^{2}}{n Δ λ} ⇒ {L}_{c} = 26.5 μm for ( λ , Δλ ) = ( 600.6 ) nm$$

The path difference due to one zig-zag is:

$$OPD = ( 2 π R + 2 R + 3 h ) - ( 2 R + h ) = 2 π R + 2 h$$

For λ=1550 nm, R≥10 μm and decreases for smaller wavelengths.

$$OPD = 83 μm > {L}_{c} = 26.5 μm ( for h = 10 μm )$$

For λ=1550 nm, an optical pathway (waveguide) width is 400 nm. Taking (Δs, Δy)=10 μm as an example value, the total width is

$${w}_{tot} = ( {N}_{cnl} - 1 ) ( 2 R + h + Δ s ) ⇒ {w}_{tot} = 4 mm for {N}_{c n l} = 100$$

The height is determined by the spacing between the channels. Assuming the channel outputs are each edge-coupled to single mode fibers, the height is

$${h}_{t o t} = {N}_{c n l} \times 125 μm ⇒ {h}_{t o t} = 12.5 mm for {N}_{c n l} = 100$$

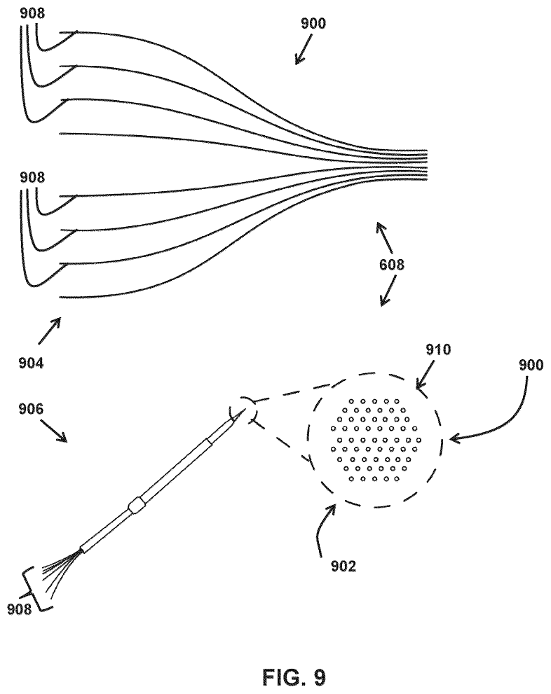

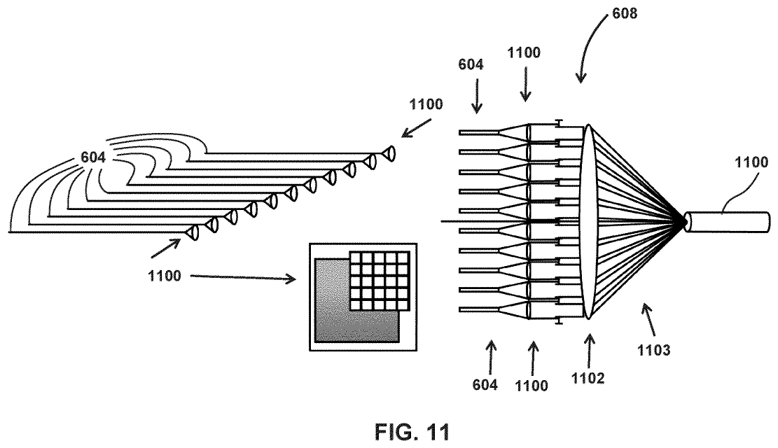

Returning to FIG. 6, combiner 608 is configured to combine the completely or partially spatially incoherent radiation into a single multimode output. In some embodiments, combiner 608 is directly coupled (e.g., without any intervening air or lens space) to corresponding optical pathways 604. After coherence scrambling by optical pathways 604, a 1D array of single mode waveguides emitting mutually incoherent light is created. Due to splitting the incident radiation from the source over N_{cnl} waveguides, system 600 has effectively increased the surface area of the radiation by a factor N_{cnl} while keeping the numerical aperture the same. This means the étendue has increased by the same factor N_{cnl}. By recombining the output from optical pathways 604 into a multimode fiber (MMF), for example, the radiation can be further processed in existing metrology system (e.g., system 10 shown in FIG. 3) illumination hardware. In some embodiments, combiner 608 comprises an optical fiber array 900 (see FIG. 9), a micro lens array 1100 and/or one or more macroscopic lenses 1102 (see FIG. 11), and/or other components.

For example, FIG. 9 illustrates combiner 608 as an optical fiber array 900. As shown in FIG. 9, after coherence scrambling, a 1D array of single mode waveguides (optical pathways 604) emitting mutually incoherent light is created. These can be recombined into a 2D profile 902 by optical fiber array 900. FIG. 9 illustrates a schematic view 904 of optical fiber array 900, a wide view 906 of fibers 908 being combined, and an end view 910 of 2D profile 902.

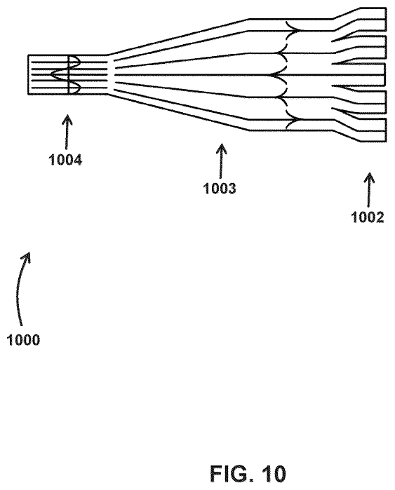

In some embodiments, combiner 608 (FIG. 6) comprises a photonic lantern. For example, FIG. 10 illustrates combiner 608 as a photonic lantern 1000. Photonic lantern 1000 is a multimode fiber device having an array of single mode fiber cores 1002. The single mode fiber cores 1002 are fused 1003 to form a multimode fiber 1004, for example.

In some embodiments, combiner 608 (FIG. 6) comprises a micro lens array and/or one or more macroscopic lenses. For example, FIG. 11 illustrates combiner 608 as a micro lens array 1100 and a macroscopic lens 1102. The output from the 1D array of single mode optical pathways 604 (waveguides) can be shaped 1103 using micro (e.g., micro lens array 1100) and/or other optical components (e.g., lens 1102). As shown in FIG. 11, placing 1D micro lens array 1100 at the same period as the output of optical pathways 604, shapes the output to an array of parallel spots. Macroscopic lens 1102 can then recombine these spots into a multimode fiber 1110.

In some embodiments, system 600 (FIG. 6) is configured such that stacked integrated optical bodies (e.g., 601 shown in FIG. 6) are formed, which together form a multidimensional array of waveguide emitters. For example, multiple planar coherence scrambling systems (e.g., multiple system 600's as described above) may be stacked on top of each other to form a 2D array of waveguide emitters (optical pathways 604). If this is fabricated at the same periodicity as a 2D micro lens array, a macroscopic lens may be used to recombine the array of spots into a multimode fiber. Using a configuration of two micro lens arrays and two macroscopic lenses, a dense array of spots may fit into an entrance aperture of the multimode fiber.

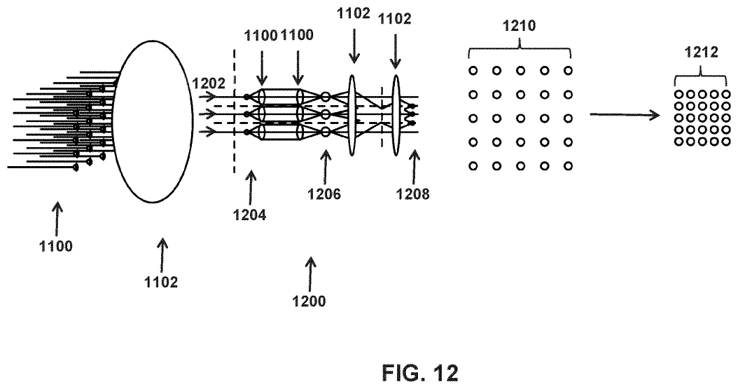

By way of a non-limiting example, FIG. 12 illustrates stacked 1200 (e.g., moving from left to right across the image) integrated optical bodies. First, FIG. 12 illustrates a 2D micro lens array and a single macroscopic lens similar to and/or the same as micro lens array 1100 and lens 1102 shown in FIG. 11. FIG. 12 then shows how stacking multiple such micro lens arrays 1100 and lenses 1102 on top of each other changes radiation 1202 from having a small spot size and large spacing 1204 to having a large spot size with large spacing 1206, then having a small spot size and small spacing 1208. FIG. 12 also illustrates how using this configuration of two micro lens arrays 1100 and two macroscopic lenses 1102, a sparse array of radiation spots 1210 may be converted into a dense array of spots 1212, which may fit into an entrance aperture of a multimode fiber.

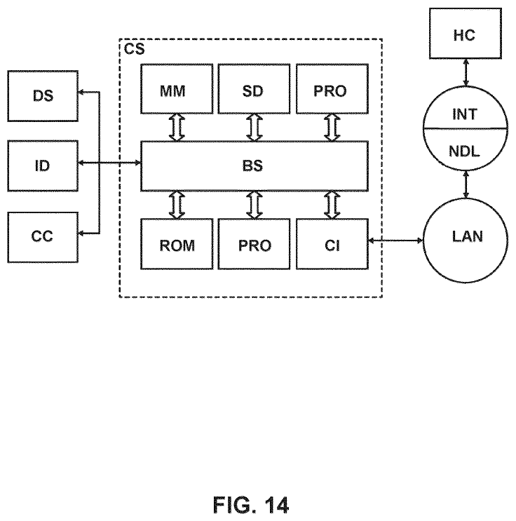

System 600 (FIG. 6) be extended with amplitude and phase modulators per channel to switch light. In some embodiments, modulation may be controlled electronically by a processor, such as processor PRO shown in FIG. 3 (and also in FIG. 14 discussed below). Processor PRO may be included in a computing system CS (FIG. 14) and may operate based on computer or machine readable instructions MRI (e.g., as described below related to FIG. 14). Electronic communication may occur by transmitting electronic signals between separate components, transmitting data between separate components of system 600, transmitting values between separate components, and/or other communication. The components of system 600 may communicate via wires or wirelessly via a network, such as the Internet or the Internet in combination with various other networks, like local area networks, cellular networks, or personal area networks, internal organizational networks, and/or other networks.

In some embodiments, one or more actuators (not shown in FIG. 6) may be coupled to and configured to move one or more components of system 600 to facilitate the modulation. The actuators may be coupled to one or components of system 600 by adhesive, clips, clamps, screws, a collar, and/or other mechanisms. The actuators may be configured to be controlled electronically. Individual actuators may be configured to convert an electrical signal into mechanical displacement and/or other modulation. The mechanical displacement and/or other modulation is configured to modulate a component of system 600. As an example, one or more of the actuators may be piezoelectric. One or more processors PRO may be configured to control the actuators. One or more processors PRO may be configured to individually control each of the one or more actuators.

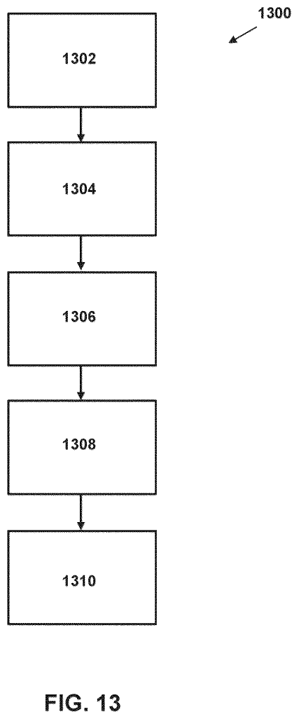

FIG. 13 illustrates a method 1300 for converting spatially coherent radiation to completely or partially spatially incoherent radiation. Method 1300 may be performed to reduce speckles in illumination for metrology as part of a semiconductor manufacturing process, for example. Method 1300 may be performed with a combination of passive integrated optical elements such that volume and threat of mechanical wear is reduced relative to mechanical coherence scramblers, for example. In some embodiments, one or more operations of method 1300 may be implemented in or by system 600 illustrated in FIG. 6, system 10 illustrated in FIG. 3, a computer system (e.g., as illustrated in FIG. 14 and described below), and/or in or by other systems, for example. In some embodiments, method 1300 comprises generating (operation 1302) spatially coherent radiation, splitting (operation 1304) the spatially coherent radiation into channels, converting (operation 1306) the spatially coherent radiation into completely or partially spatially incoherent radiation, combining (operation 1308) the completely or partially spatially incoherent radiation into a single multimode output, receiving and directing (operation 1310) the single multimode output for metrology, and/or other operations.

The operations of method 1300 are intended to be illustrative. In some embodiments, method 1300 may be accomplished with one or more additional operations not described, and/or without one or more of the operations discussed. For example, in some embodiments, method 1300 may include additional operations related to determining an adjustment for a semiconductor device manufacturing process. Additionally, the order in which the operations of method 1300 are illustrated in FIG. 13 and described herein is not intended to be limiting.

In some embodiments, one or more portions of method 1300 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1300 in response to instructions stored electronically on an electronic storage medium. The one or more processing devices may include one or more devices configured through hardware, firmware, and/or software to be specifically designed for execution of one or more of the operations of method 1300 (e.g., see discussion related to FIG. 14 below).

At operation 1302, spatially coherent radiation is generated. The radiation may have a target wavelength and/or wavelength range, a target intensity, and/or other characteristics. The target wavelength and/or wavelength range, the target intensity, etc., may be entered and/or selected by a user, determined by the system (e.g., system 10 shown in FIG. 3) based on previous measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry. In this example, the spatially coherent radiation may be considered to be visible light. In some embodiments, the spatially coherent radiation is generated by a single source configured to generate the radiation along a first axis. In some embodiments, operation 1302 is performed by a radiation source similar to and/or the same as source 2 shown in FIG. 3).

At operation 1304, the spatially coherent radiation is split into channels. In some embodiments, the spatially coherent radiation is split into at least 2-100 channels, for example. In some embodiments, operation 1304 is performed by a splitter that is the same as or similar to splitter 602 shown in FIG. 6 and described above. In some embodiments, the splitter comprises a binary tree beam splitter or a non-binary beam splitter. In some embodiments, the splitter comprises a multimode interference (MMI) device, for example.

At an operation 1306, the spatially coherent radiation is converted into completely or partially spatially incoherent radiation. In some embodiments, operation 1306 is performed by optical pathways that are the same as or similar to optical pathways 604 shown in FIG. 6 and described above. Each optical pathway may comprise a waveguide and form a portion of a corresponding channel, for example. The optical pathways have different lengths and are coupled to the channels. The different lengths are configured to convert the spatially coherent radiation conducted by the optical pathways to the completely or partially spatially incoherent radiation. The different lengths are configured to reduce or eliminate interference between radiation traversing different optical pathways, which converts the spatially coherent radiation to the completely or partially spatially incoherent radiation. The optical pathways are configured such that radiation in a single channel does not become incoherent since it is single mode radiation, but with an appropriate path difference, radiation in the single channel becomes incoherent with respect to radiation in neighboring channels. In some embodiments, an optical path length difference from a first optical pathway to a second optical pathway (and from the first to a third, the second to the third, and so on) is larger than a coherence length of the spatially coherent radiation.

At an operation 1308, the completely or partially spatially incoherent radiation is combined into a single multimode output. In some embodiments, operation 1308 is performed by a combiner that is the same as or similar to combiner 608 shown in FIG. 6 and described above. In some embodiments, the combiner comprises an optical fiber array. In some embodiments, the combiner comprises a photonic lantern. In some embodiments, the combiner comprises a micro lens array and/or one or more macroscopic lenses.

At operation 1310, the single multimode output from the combiner is received and the completely or partially spatially incoherent radiation is directed for metrology. In some embodiments, operation 1310 is performed by a multimode fiber configured to receive the single multimode output from the combiner and direct the completely or partially spatially incoherent radiation for metrology. In some embodiments, operation 1310 is performed by various components of a system such as system 10 illustrated in FIG. 3, e.g., including detector 4 and processor PRO, etc. For example, the system may comprise a controller (e.g., processor PRO) configured to actively control output from individual optical pathways.

In some embodiments, overlay and/or alignment and/or other measurements may be determined at operation 1310. Overlay and/or alignment may be determined based on reflected diffracted radiation from a diffraction grating target and/or other information. For example, in some embodiments, operation 1310 includes illuminating (and/or otherwise irradiating) one or more targets (e.g., target 30 shown in FIG. 3) in a patterned substrate with radiation. The radiation comprises the completely and/or partially spatially incoherent radiation described above. The radiation may be generated by a radiation source (e.g., source 2 shown in FIG. 3 described above). In some embodiments, the radiation may be directed onto multiple targets, a single target, sub-portions (e.g., something less than the whole) of a target, and/or onto a substrate in other ways. In some embodiments, the radiation may be directed onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

In some embodiments, operation 1310 comprises generating a metrology signal based on the detected reflected radiation from diffraction grating target(s), as described above. The metrology signal is generated by a sensor (such as detector 4 in FIG. 3 and/or other sensors) based on radiation received by the sensor. The metrology signal comprises measurement information pertaining to the target(s). For example, the metrology signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The metrology signal comprises an electronic signal that represents and/or otherwise corresponds to the radiation reflected from the target(s). The metrology signal may indicate a metrology value associated with a diffraction grating target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This may include generating and/or analyzing one or more images of a target, using the radiation described herein. This sensing and converting may be performed by components similar to and/or the same as detector 4 and/or processors PRO shown in FIG. 3, and/or other components.

In some embodiments, method 1300 comprises determining an adjustment for a semiconductor device manufacturing process. In some embodiments, method 1300 includes determining one or more semiconductor device manufacturing process parameters. The one or more semiconductor device manufacturing process parameters may be determined based on one or more detected phase and/or amplitude variations, an overlay and/or alignment value indicated by the metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1300 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1300), for example. In some embodiments, method 1001 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 14 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:

1. A system configured to convert spatially coherent radiation to completely or partially spatially incoherent radiation, the system comprising: a splitter configured to receive and split the spatially coherent radiation into channels; optical pathways having different lengths coupled to the channels, the different lengths configured to convert the spatially coherent radiation to the completely or partially spatially incoherent radiation; and a combiner coupled to the optical pathways and configured to combine the completely or partially spatially incoherent radiation from the optical pathways into a single multimode output.

2. The system of clause 1, wherein the optical pathways are configured such that radiation in a single channel does not become incoherent since it is single mode radiation, but with an appropriate path difference, radiation in the single channel becomes incoherent with respect to radiation in neighboring channels.

3. The system of any of the previous clauses, wherein the splitter, the optical pathways, and the combiner are integrated into an integrated optical body.

4. The system of any of the previous clauses, wherein the integrated optical body comprises a microchip fabricated using complementary metal-oxide-semiconductor (CMOS) and/or indium phosphide fabrication techniques.

5. The system of any of the previous clauses, wherein a waveguiding layer of the integrated optical body is formed from silicon, silicon-on-oxide, indium phosphide, silicon nitride, and/or aluminum oxide.

6. The system of any of the previous clauses, wherein the system comprises stacked integrated optical bodies that form a multidimensional array of waveguide emitters.

7. The system of any of the previous clauses, wherein the system is passive, having no moving parts or electrically controlled components.

8. The system of any of the previous clauses, wherein the splitter is configured to split the spatially coherent radiation into at least 2-100 channels.

9. The system of any of the previous clauses, wherein the splitter is a binary tree beam splitter or a non-binary beam splitter.

10. The system of any of the previous clauses, wherein the splitter is a multimode interference (MMI) device.

11. The system of any of the previous clauses, wherein each optical pathway comprises a waveguide and forms a portion of a corresponding channel.

12. The system of any of the previous clauses, wherein the different lengths are configured to reduce or eliminate interference between radiation traversing different optical pathways, which converts the spatially coherent radiation to the completely or partially spatially incoherent radiation.

13. The system of any of the previous clauses, wherein an optical path length difference from a first optical pathway to a second optical pathway is larger than a coherence length of the spatially coherent radiation.

14. The system of any of the previous clauses, wherein the combiner comprises an optical fiber array.

15. The system of any of the previous clauses, wherein the combiner comprises a photonic lantern.

16. The system of any of the previous clauses, wherein the combiner comprises a micro lens array and/or one or more macroscopic lenses.

17. The system of any of the previous clauses, wherein the spatially coherent radiation comprises visible light.

18. The system of any of the previous clauses, wherein the system further comprises a multimode fiber configured to receive the single multimode output from the combiner.

19. The system of any of the previous clauses, wherein the system further comprises a controller configured to actively control output from individual optical pathways.

20. The system of any of the previous clauses, wherein the spatially coherent radiation is converted to the completely or partially spatially incoherent radiation for metrology associated with a semiconductor manufacturing process.

21. A method for converting spatially coherent radiation to completely or partially spatially incoherent radiation, the method comprising: receiving and splitting, with a splitter, the spatially coherent radiation into channels; converting, with optical pathways having different lengths coupled to the channels, the spatially coherent radiation to the completely or partially spatially incoherent radiation; and combining, with a combiner coupled to the optical pathways, the completely or partially spatially incoherent radiation from the optical pathways into a single multimode output.

22. The method of any of the previous clauses, wherein the optical pathways are configured such that radiation in a single channel does not become incoherent since it is single mode radiation, but with an appropriate path difference, radiation in the single channel becomes incoherent with respect to radiation in neighboring channels.

23. The method of any of the previous clauses, wherein the splitter, the optical pathways, and the combiner are integrated into an integrated optical body.

24. The method of any of the previous clauses, wherein the integrated optical body comprises a microchip fabricated using complementary metal-oxide-semiconductor (CMOS) and/or indium phosphide fabrication techniques.

25. The method of any of the previous clauses, wherein a waveguiding layer of the integrated optical body is formed from silicon, silicon-on-oxide, indium phosphide, silicon nitride, and/or aluminum oxide.

26. The method of any of the previous clauses, further comprising forming stacked integrated optical bodies that form a multidimensional array of waveguide emitters.

27. The method of any of the previous clauses, wherein the splitter, the optical pathways, and the combiner, have no moving parts or electrically controlled components.

28. The method of any of the previous clauses, further comprising splitting, with the splitter, the spatially coherent radiation into at least 2-100 channels.

29. The method of any of the previous clauses, wherein the splitter is a binary tree beam splitter or a non-binary beam splitter.

30. The method of any of the previous clauses, wherein the splitter is a multimode interference (MMI) device.

31. The method of any of the previous clauses, wherein each optical pathway comprises a waveguide and forms a portion of a corresponding channel.

32. The method of any of the previous clauses, wherein the different lengths are configured to reduce or eliminate interference between radiation traversing different optical pathways, which converts the spatially coherent radiation to the completely or partially spatially incoherent radiation.

33. The method of any of the previous clauses, wherein an optical path length difference from a first optical pathway to a second optical pathway is larger than a coherence length of the spatially coherent radiation.

34. The method of any of the previous clauses, wherein the combiner comprises an optical fiber array.

35. The method of any of the previous clauses, wherein the combiner comprises a photonic lantern.

36. The method of any of the previous clauses, wherein the combiner comprises a micro lens array and/or one or more macroscopic lenses.

37. The method of any of the previous clauses, wherein the spatially coherent radiation comprises visible light.

38. The method of any of the previous clauses, further comprising receiving, with a multimode fiber, the single multimode output from the combiner.

39. The method of any of the previous clauses, further comprising actively controlling, with a controller, output from individual optical pathways.

40. The method of any of the previous clauses, wherein the spatially coherent radiation is converted to the completely or partially spatially incoherent radiation for metrology associated with a semiconductor manufacturing process.

41. A system configured to convert spatially coherent radiation to completely or partially spatially incoherent radiation to reduce speckles in illumination for metrology as part of a semiconductor manufacturing process, the system configured with a combination of passive integrated optical elements such that volume and threat of mechanical wear is reduced relative to mechanical coherence scramblers, the system comprising: a source configured to generate the spatially coherent radiation; a passive integrated optical body, the body comprising: a splitter configured to receive and split the spatially coherent radiation into channels, wherein the splitter comprises a binary tree beam splitter and/or a multimode interference (MMI) device; optical pathways having different lengths coupled to the channels, the different lengths configured to convert the spatially coherent radiation conducted by the optical pathways to the completely or partially spatially incoherent radiation, the different lengths configured to reduce or eliminate interference between radiation traversing different optical pathways, which converts the spatially coherent radiation to the completely or partially spatially incoherent radiation, the optical pathways configured such that radiation in a single channel does not become incoherent since it is single mode radiation, but with an appropriate path difference, radiation in the single channel becomes incoherent with respect to radiation in neighboring channels; and a combiner configured to combine the completely or partially spatially incoherent radiation from the optical pathways into a single multimode output; and a multimode fiber configured to receive the single multimode output from the combiner and direct the completely or partially spatially incoherent radiation for metrology.

42. The system of any of the previous clauses, wherein the passive integrated optical body comprises a silicon, silicon-on-oxide, indium phosphide, silicon nitride, and/or aluminum oxide microchip.

43. The system of any of the previous clauses, wherein the system comprises stacked integrated optical bodies that form a multidimensional array of waveguide emitters.

44. The system of any of the previous clauses, wherein an optical path length difference from a first optical pathway to a second optical pathway is larger than a coherence length of the spatially coherent radiation.

45. The system of any of the previous clauses, wherein the combiner comprises an optical fiber array, a photonic lantern, a micro lens array, and/or one or more macroscopic lenses.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition, the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A system configured to convert spatially coherent radiation to completely or partially spatially incoherent radiation, the system comprising:
a splitter configured to receive and split the spatially coherent radiation into channels;
optical pathways having different lengths coupled to the channels, the different lengths configured to convert the spatially coherent radiation to the completely or partially spatially incoherent radiation; and
a combiner coupled to the optical pathways and configured to combine the completely or partially spatially incoherent radiation from the optical pathways into a single multimode output.

2. The system of claim 1, wherein the optical pathways are configured such that radiation in a single channel does not become incoherent since it is single mode radiation, but with an appropriate path difference, radiation in the single channel becomes incoherent with respect to radiation in neighboring channels.

3. The system of claim 1, wherein the splitter, the optical pathways, and the combiner are integrated into an integrated optical body.

4. The system of claim 3, wherein the integrated optical body comprises a microchip fabricated using complementary metal-oxide-semiconductor (CMOS) and/or indium phosphide fabrication techniques.

5. The system of claim 3, wherein a waveguiding layer of the integrated optical body is formed from silicon, silicon-on-oxide, indium phosphide, silicon nitride, and/or aluminum oxide.

6. The system of claim 1, comprising stacked integrated optical bodies that form a multidimensional array of waveguide emitters.

7. The system of claim 1, wherein the system is passive, having no moving parts or electrically controlled components.

8. The system of claim 1, wherein the splitter is configured to split the spatially coherent radiation into at least 2-100 channels.

9. The system of claim 1, wherein the splitter is a binary tree beam splitter or a non-binary beam splitter.

10. The system of claim 1, wherein the splitter is a multimode interference (MMI) device.

11. The system of claim 1, wherein each optical pathway comprises a waveguide and forms a portion of a corresponding channel.

12. The system of claim 1, wherein the different lengths are configured to reduce or eliminate interference between radiation traversing different optical pathways, which converts the spatially coherent radiation to the completely or partially spatially incoherent radiation.

13. The system of claim 1, wherein an optical path length difference from a first optical pathway to a second optical pathway is larger than a coherence length of the spatially coherent radiation.

14. The system of claim 1, wherein the combiner comprises an optical fiber array.

15. The system of claim 1, wherein the combiner comprises a photonic lantern.

16. The system of claim 1, wherein the combiner comprises a micro lens array and/or one or more macroscopic lenses.

17. The system of claim 1, wherein the spatially coherent radiation comprises visible light.

18. The system of claim 1, further comprising a multimode fiber configured to receive the single multimode output from the combiner.

19. The system of claim 1, further comprising a controller configured to actively control output from individual optical pathways.

20. The system of claim 1, wherein the spatially coherent radiation is converted to the completely or partially spatially incoherent radiation for metrology associated with a semiconductor manufacturing process.
